(19) United States
(12) Patent Application Publication
(10) Pub. No.: US 2025/0185187 A1
(43) Pub. Date: Jun. 5, 2025

(54) MODULAR FIELD DEVICE

(71) Applicant: ENDRESS+HAUSER SE GMBH+CO. KG, Maulburg (DE)

(72) Inventor: Robert Schmidt, Schopfheim (DE)

(21) Appl. No.: 18/842,150

(22) PCT Filed: Feb. 7, 2023
(86) PCT No.: PCT/EP2023/052976

§ 371 Date: Aug. 28, 2024

(30) Foreign Application Priority Data
Feb. 28, 2022 (DE) 10 2022 104 763.6

(51) Int. Cl. H05K 5/00; H01R 12/70; H01R 12/71; H05K 1/18

(52) U.S. Cl. CPC H05K 5/0069; H01R 12/7005; H01R 12/716; H05K 1/181

(57) ABSTRACT

A modular field device includes two electronic modules with a first electronics module secured in a housing inner space. A second electronics module is mechanically and electrically connectable with the first electronics module. Serving for electrical contacting is a plug contact composed of plug- and corresponding socket arrangements. In such case, the plug contact comprises a circuit board, on which one of the arrangements is soldered, and a corresponding circuit board seat at one of the electronic modules. The circuit board seat includes a circuit board guide and an end stop element for the arrangements associated therewith. During manufacture, the circuit board is introduced into the guide. Because according to the invention the end stop is, however, formed on the arrangement and not on the circuit board, no unintended force is exerted on the solder sites between circuit board and the arrangement located thereon.

The invention relates to a modular field device, which can be produced easily and safely.

In automation technology, for example, for large industrial process plants, field devices are often applied, which serve for registering relevant process parameters of process media. Suitable measuring principles are applied for registering the process parameters. Corresponding sensors are applied in, among others, limit level measuring devices, fill level measuring devices, flowmeters, pressure- and temperature measuring devices, pH-redox potential measuring devices, conductivity measuring devices, etc. These register in the containers, pipes or tubes, in which the process medium is located, the process parameters of interest, such as the fill level, the flow, the pressure, the temperature, the pH value, the redox potential, the conductivity or the dielectrical value. A large number of such field devices are manufactured and sold by the firm, Endress+Hauser.

Increasingly, field devices are modularly designed. Modular design means for the case of field devices that different field device types, such as, for example, pressure measuring devices, limit level measuring devices and fill level measuring devices, are constructed in part from identical modules, or components. The application of identical components in different field device types is advantageous, above all, in the case of those electronic modules, which perform higher-level functions, such as, for example, communication or measurement data processing. Thus, a significant cost reduction can be effected in the case of development and manufacturing logistics of new field device types by using a modular design of individual components.

However, the assembly of a field device type can be made difficult by this modular design, since the number of components, especially electronic modules, increases while the available space in the housing interior of the field device remains constant. At the same time, the individual electronic modules need to be connected electrically, and/or mechanically, both with one another, as well as also with the housing. Thus, the more complex question of how to get all the parts into a given space makes the actual production of the field device more difficult. In the international publication WO 2019038266 A1, indeed, a field device is disclosed, in the case of which two electronic modules are mechanically connectable with one another and accordingly can be arranged space savingly in the inner space of a housing. A suitable electrical contacting of the two electronic modules with one another is, however, not described.

An object of the invention, therefore, is to provide a modular field device, which can be produced both mechanically as well as also electrically easily and safely.

The invention achieves the object by a field device comprising:
a housing having an inner space,
a first electronics module secured in the inner space,
a second electronics module arranged in the inner space,
a mechanical securement, by means of which the second electronics module is securable to the first electronics module along a defined plug-in vector to form a mechanical connection, and
an electrical plug contact, via which the second electronics module is electrically contactable with the first electronics module correspondingly to the mechanical connection in the direction of the plug-in vector, with
   a plug arrangement and a socket arrangement corresponding to the plug arrangement, wherein the arrangements can be designed, for example, as SMD components or as THT components,
   a first circuit board having a surface, on which either the plug arrangement or the socket arrangement is arranged in such a manner that the plugs, or sockets, are oriented in parallel with the surface, and
   a circuit board seat, which is arranged at one of the two electronic modules, with
      a first guide, by means of which the first circuit board is guidable in parallel with the plug-in vector, and
      at least one end stop element, which forms in the first guide counter to the plug-in vector an end stop for the corresponding socket-, or plug, arrangement of the first circuit board.

That of the two arrangements, which is not secured to the first circuit board, is correspondingly arranged on that electronics module, to which the circuit board seat is not secured. The design of the mechanical securement on the electronic modules is not fixedly predetermined within the scope of the invention. The securement can comprise, for example, three equally distributed engagement tabs and corresponding projections.

Among the advantages of the design of the electrical plug contact of the invention is that when securing the electronic modules with one another as well as during preceding plugging in of the first circuit board in the first guide no force is exerted on the solder sites between the first circuit board and the socket or plug arrangement located thereon.

The terminology, “module”, in the context of the invention means, in principle, a separate arrangement, or encapsulation, of those electronic circuits, which are provided for a particular application, for example, for measurement signal processing or as an interface. The particular module can, thus, depending on application, comprise corresponding analog circuits for producing or processing analog signals. The modules can, however, also comprise digital circuits, such as FPGAs, microcontrollers, or storage media in cooperation with corresponding programs. In such case, the program is designed to perform the required method steps and, thus, to apply the needed computer operations. In this context, different electronic circuits of the unit can, within the scope of the invention, potentially also use a shared physical memory, or be operated by means of the same physical, digital circuit. In such case, it does not matter whether different electronic circuits within the module are arranged on a shared circuit board or on a number of connected circuit boards.

When that electronics module, on which the circuit board seat is arranged, is based on a second circuit board, which is oriented orthogonally to the plug-in vector, the circuit board seat, and the corresponding socket or plug arrangement, does need to be arranged relative to the plug-in vector behind, or above, the second circuit board, in order that the electrical plug contact can be completed. An advantageous further development provides, in such case, that the circuit board seat is designed especially as an integral component of a potting compound form for the second circuit board. This reduces the number of needed components.

Advantageously, moreover, the circuit board seat of the invention has on sides of that surface of the first circuit board, on which the corresponding arrangement is arranged, a yoke extending orthogonally to the plug-in vector. When, in such case, the first circuit board is connected electrically with the second circuit board via a flexible circuit board or a flexible cable, the cable can be led in the form of a defined loop around the yoke during the manufacturing. In this way, the cable, or the flexible circuit board, is sufficiently secured, in order no longer to be susceptible to damage. Moreover, the yoke can be structurally so designed that it surrounds in the circuit board seat an inner surface, which is smaller than the minimum possible extent of the corresponding arrangement on the first circuit board. This prevents a pushing of the first circuit board into the first guide from the wrong side.

In order to affix the first circuit board in the circuit board seat in the direction of the plug-in vector, an engagement hook can be provided opposite that surface of the first circuit board, on which the corresponding arrangement is arranged. In such case, the engagement hook provides in the first guide in the direction of the plug-in vector a corresponding end stop for the first circuit board after engagement. Above all in the case of such a design with engagement hook, the circuit board seat advantageously forms a second guide, which orthogonally guides the corresponding plug or socket arrangement relative to the surface of the first circuit board. This facilitates the engagement.

Moreover, the engagement hook in the engaged state advantageous exerts a compressive force on the first circuit board orthogonally to the surface of the first circuit board. In this way, the first circuit board is secured in a defined position within the first guide, in spite of possible excess tolerance, such that the completion of the plug contact is facilitated.

Minimum method steps as follows are necessary, in order to produce the field device of the invention:
inserting the first circuit board into the guide grooves of the first guide of the circuit board seat,
mechanical and electrical connecting of the second electronics module to the first electronics module, in that
   the socket arrangement is oriented relative to the plug-in vector aligned with the plug arrangement, and
   the second electronics module is guided in the direction of the plug-in vector to accomplish the mechanical and electrical plugging in, and
securing the first electronics module in the inner space of the housing of the field device.

The invention will now be explained in greater detail based on the appended drawing, the figures of which show as follows:

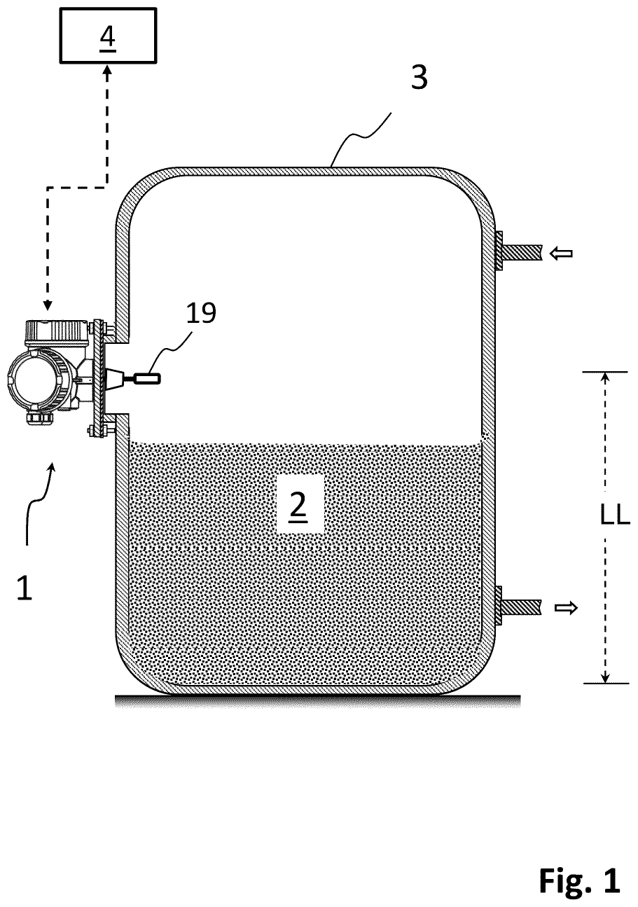

FIG. 1 a vibronic limit level measuring device mounted on a container,

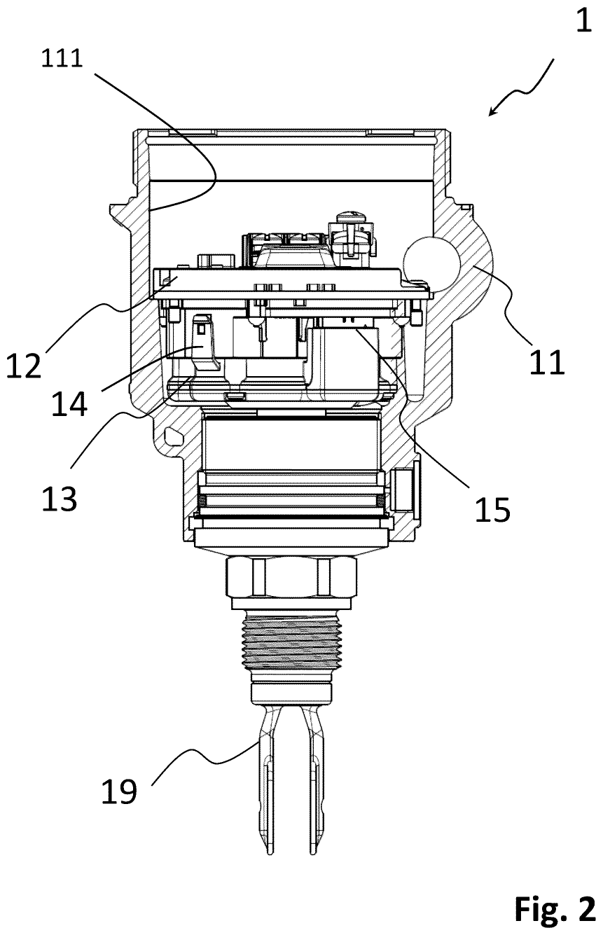

FIG. 2 a sectional view of the limit level measuring device of the invention,

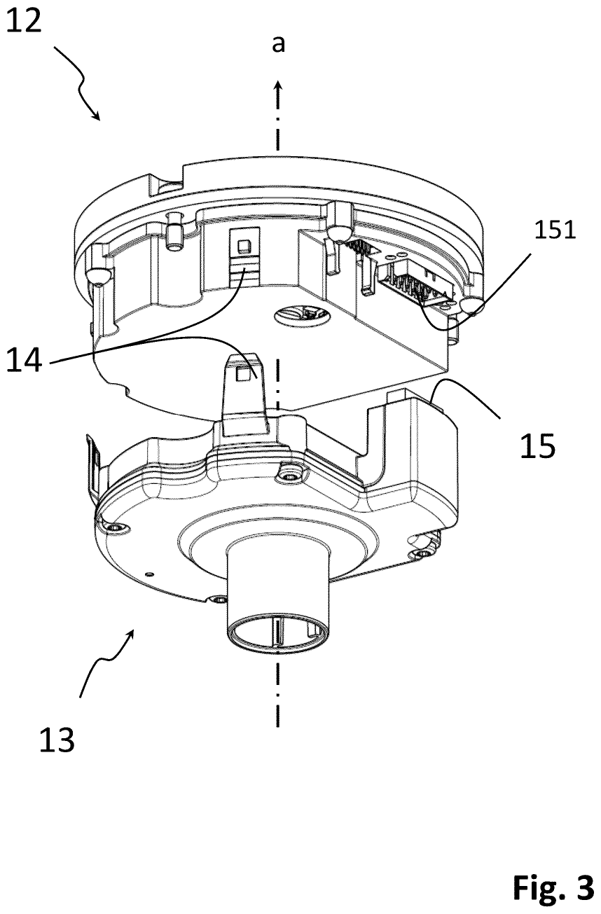

FIG. 3 in an exploded view, the securing of two electronic modules of the limit level measuring device of the invention with one another,

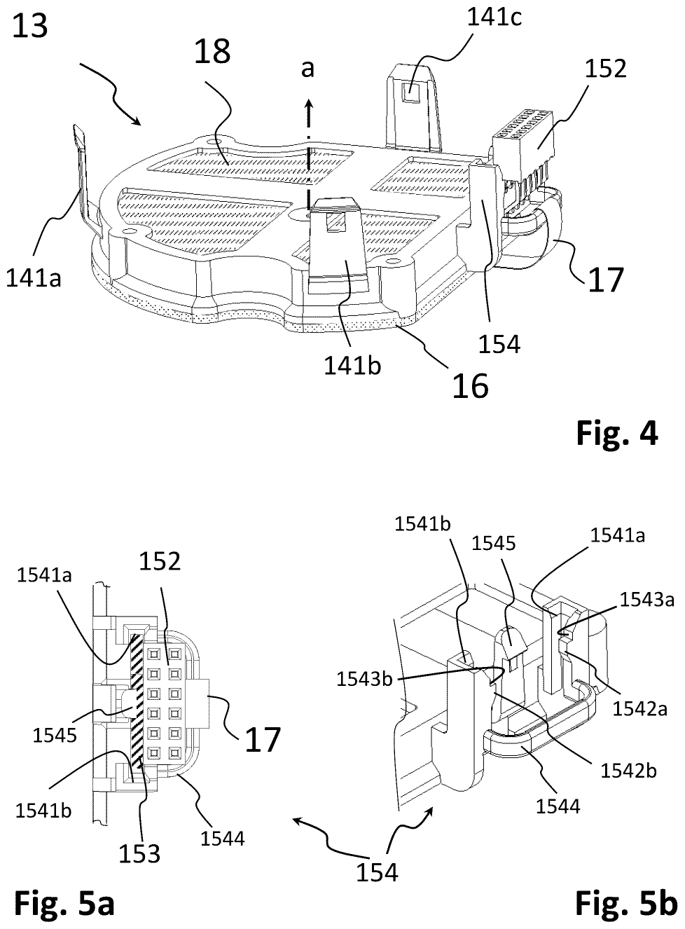

FIG. 4 the second electronics module with the circuit board seat of the invention, and

FIG. 5 two detail views in the region of the circuit board seat for the electrical contacting of the two electronic modules.

In the following, ideas of the invention will be explained in greater detail based on vibronic limit level detection. For an understanding of the invention in principle, FIG. 1 shows a container 3 of an industrial process plant. Container 3 contains a fill substance 2, wherein a possible reaching of a limit level LL of the fill substance 2 is to be determined, for example, in order to control in- or outflows of the container 3. Container 3 can, depending on type of fill substance 2 and depending on field of application, extend to more than 100 m high. Conditions in the container 3 also depend on the type of fill substance 2 and the field of application. Thus, for example, in the case of exothermic reactions, excessive temperature- and pressure loading can be present. In the case of dust containing or otherwise ignitable materials, corresponding explosion protection requirements must be maintained in the container interior. In order to determine the limit level LL, a field device 1 in the form of a vibronic limit level measuring device 1 is arranged on an outer side wall of the container 3 at the height of the limit level LL to be registered, in such a manner that only a mechanically oscillatable body 19, such as an oscillatory fork, extends into the interior of the container 3. Functioning as connection for the limit level measuring device 1 to the container 3 can be, for example, a flange connection. Relative to the general functional principle of vibronic limit level measurement, reference is made, by way of example, to the publication DE 10 2010 040 219 A1.

As a rule, the limit level measuring device 1 is connected via a separate interface, such as, for instance, “4-20 mA”, “PROFIBUS”, “HART”, or “Ethernet”, to a superordinated unit 4, such as e.g. a local process control system or a decentral server system. A detected limit level LL can be transmitted to the superordinated unit 4, in order, for example, to control in- or outflows of the container 3. However, also other information concerning general operating state of the limit level measuring device 1 can be communicated.

As can be seen from the sectional view of the limit level measuring device 1 in FIG. 2, the electronic components are divided among two modules 12, 13, in order to be able to provide platform based manufacture of the limit level measuring device 1. In such case, the first electronics module 12 comprises electronic components for communication with the superordinated unit 4, components which can also be applied in other field device types. The second electronics module 13 comprises the electrical components specific for limit level determination. The sectional view of the limit level measuring device 1 in FIG. 2 illustrates that the two electronic modules 12, 13 are arranged together in an inner space 111 of a housing 11 of the limit level measuring device 1, which after mounting of the limit level measuring device 1 at the site of use is located mostly outside of the container 3. The oscillatory fork 19, in turn, via a screw thread adjoins the housing 11 in such a manner, such that, after mounting, it extends into the container interior. The first electronics module 12 is secured to a peripheral projection in the inner space 111 of the limit level measuring device 1, for example, by means of screw connections. The second electronics module 13 is not directly secured in the inner space 111, but, instead, only indirectly, in that the second electronics module 13 is secured to the first electronics module 12.

FIG. 3 illustrates a securement of the second electronics module 13 to the first electronics module 12. The mechanical securement 14 of the electronic modules 12, 13 with one another occurs in the illustrated example of an embodiment via three, second engagement tabs 141a, b, c on the second electronics module 13 as well as corresponding projections on the first electronics module 12. In such case, the three engagement tabs 141a, b, c are arranged equally distributed with 120° spacings about a plug-in vector a in such a manner that the second electronics module 13 is engageable with the first electronics module 12 in the direction of the plug-in vector a.

As can be seen from the exploded view of FIG. 3, the second electronics module 13 is connected not only mechanically, but, instead, also electrically with the first electronics module 12, and, indeed, via a plug contact 15. For this, the plug contact 15 comprises in the first electronics module 12 a plug arrangement 151, which is oriented counter to the plug-in axis a. The second electronics module 13 comprises a socket arrangement 152 corresponding to the plug arrangement 151. In such case, the plug contact 15 is designed corresponding to the engagement tabs 141a, b, c, and the projections. This means that when the engagement tabs 141a, b, c of the second electronics module 13 are aligned relative to the plug-in vector a suitably for engaging the projections on the first electronics module 12, then with respect to plug-in vector a also automatically the position of the plug arrangement 151 agrees with the position of the socket arrangement 152. In this way, the two electronic modules 12, 13 can be simultaneously electrically and mechanically connected with one another, in that, relative to the plug-in vector a, the engagement tabs 141a, b, c are oriented aligned with the projections (and the plug arrangement 151 is oriented aligned with the socket arrangement 152), such that the modules 12, 13 can then be plugged together along the plug-in vector a. In such case, the engagement tabs 141a, b, c serve at the same time for guiding this to happen.

FIG. 4 illustrates the electrical plug contact 15 of the invention in greater detail. Only the second electronics module 13 is included in the figure. In the illustrated embodiment, the second electronics module 13 is based on a second circuit board 16, wherein the plug-in vector a extends orthogonally to the second circuit board 16. Due to field device specific, explosion protection specifications, the second circuit board 16 is encapsulated with a gel-type potting compound 18, for example, SILGel®. In such case, the corresponding potting form on the circuit board 16 includes a seat 154 for the socket arrangement 152 of the electrical plug contact 15. Since the socket arrangement 152, and the plug arrangement 151, are implemented, as a rule, as SMD components or as THT components, the seat 154, however, secures primarily not the socket arrangement 152, but, instead, firstly, the first circuit board 153, to which the socket arrangement 152 is soldered. In such case, the socket arrangement 152 is arranged on the first circuit board 153 in such a manner that its sockets are oriented orthogonally to that circuit board surface, to which the socket arrangement 152 is soldered, thus in parallel with the plug-in vector a.

As can be seen, moreover, from FIG. 4, it is constructively necessary that the circuit board seat 154, and thus the socket arrangement 152, are arranged relative to the plug-in vector a behind, or above, the second circuit board 16, at the height of the engagement tabs 141a, b, c, in order that the electrical plug contact 15 can be closed. The socket arrangement 152, and thus the first circuit board 153, are electrically connected with the second circuit board 16 in the illustrated embodiment via a flexible circuit board 17. For manufacturing purposes, it is, in such case, necessary that the flexible circuit board 17 has a defined excess length, in order that the first circuit board 153 during the manufacturing of the limit level measuring device 1 can be inserted counter to the plug-in vector a into guide grooves 1541a, b of a first guide of the circuit board seat. Two detail views of the circuit board seat 154, which illustrate this in detail, are provided by FIGS. 5a and 5b:

According to the invention, the circuit board seat 154 forms the two opposite guide grooves 1541a, b for the first circuit board 153 as an integral component. In order to secure the first circuit board 153 after insertion into the grooves 1541a, b counter to the plug-in vector a, the circuit board seat 154 forms in this direction on the two grooves 1541a, b according to the invention, moreover, two corresponding end stop elements 1542a, b for the socket arrangement 152. Advantageous in this is that during securing of the electronic modules 12, 13 with one another, and in the connecting of the plug contact 14 as well as during preceding plugging in of the first circuit board 153 into the guide grooves 1541a, b, no force is exerted on the solder sites between the first circuit board 153 and the socket arrangement 152. In the opposite direction, thus, in the direction of the plug-in vector a, the first circuit board 153, after being pushed into the grooves 1541a, b to the end stop elements 1543a, b, becomes secured by a corresponding engagement hook 1545. This is especially to be recognized on the basis of FIG. 5b.

As is clear from FIG. 5b, the engagement hook 1545 is additionally thickened toward the first circuit board 153 in such a manner that in the engaged state it presses the first circuit board 153 away, for instance, orthogonally to the surface of the first circuit board 153. In this way, the first circuit board 153—and, thus, the socket arrangement 152—have in the engaged state a defined position within the guide grooves 1541a, b. The thickening on the engagement hook 1545 facilitates, thus, the completion of the electrical contact 15 during the securing of the two electronic modules 12, 13 with one another. Moreover, the two end stop elements 1543a, b form for the socket arrangement 152 virtually a second guide 1543a, b for the socket arrangement 152: In this way, the socket arrangement 152 and the first circuit board 153 are guided orthogonally with reference to the surface of the first circuit board 153, thus virtually in parallel with the second circuit board 16. In such case, a guidance for the thickness of the first circuit board 153 is only possible in the tolerance range of the guide grooves 1541. This supports the first circuit board 153 when engaging in the engagement hook 1545.

Furthermore, the circuit board seat 154 includes in the embodiment shown in FIGS. 4 and 5 on sides of the surface of the first circuit board 153, on which the socket arrangement 152 is arranged, a yoke 1544 extending as an integral component orthogonally to the plug-in vector a. The flexible circuit board 17 forms a defined loop around the yoke 1544 when the first circuit board 153 is inserted into the first guide 1541a, b. In this way, the flexible circuit board 17 is secured for subsequent manufacture of the limit level measuring device 1 and cannot be accidentally damaged. Furthermore, the yoke 1544 in the illustrated embodiment is so designed that that inner area surrounded by the yoke 1544 in the circuit board seat 154 is less than the minimum conceivable extent of the socket arrangement 152. In this way, it is excluded that an attempt is made to insert the first circuit board 153, and, thus, the socket arrangement 152 during manufacturing of the limit level measuring device 1 incorrectly in the direction of the plug-in vector a into the first guide 1541a, b.

In the case of the embodiment of the limit level measuring device 1 of the invention shown in FIG. 3-FIG. 5, the socket arrangement 152 is associated with the second electronics module 13, while the corresponding plug arrangement 151 is arranged on the first electronics module 12. In this regard, it is, of course, acceptable within the scope of the invention that the arrangements 151, 152 can also, be placed conversely on the modules 12, 13. I.e., the socket arrangement 152 is arranged on the first electronics module 12, while the plug arrangement 151 goes on the second electronics module 13, or the first circuit board 153.

### LIST OF REFERENCE CHARACTERS

1 field device
2 fill substance
3 container
4 superordinated unit
11 housing
12 first electronics module
13 second electronics module
14 mechanical securement
15 electrical plug contact
16 second circuit board
17 flexible circuit board
18 potting compound
19 oscillatable body
111 inner space of the housing
141 engagement tab
151 plug arrangement
152 socket arrangement
153 first circuit board
154 circuit board seat
1541 guide grooves of the first guide
1542 end stop element
1543 second guide
1544 yoke
1545 engagement hook
a plug-in vector
LL limit level

1-11. (canceled)

12. A field device, comprising:
a housing having an inner space,
a first electronics module secured in the inner space,
a second electronics module arranged in the inner space,
a mechanical securement, by means of which the second electronics module is securable to the first electronics module along a defined plug-in vector to form a mechanical connection, and
an electrical plug contact, via which the second electronics module is electrically contactable with the first electronics module correspondingly to the mechanical connection in the direction of the plug-in vector, with
a plug arrangement,
a socket arrangement corresponding to the plug arrangement,
a first circuit board having a surface, on which either the plug arrangement or the socket arrangement is arranged in such a manner that the plugs, or sockets, are oriented in parallel with the surface, and
a circuit board seat, which is arranged at one of the two electronic modules, with
a first guide, by means of which the first circuit board is guidable in parallel with the plug-in vector, and
at least one end stop element, which forms in the first guide counter to the plug-in vector an end stop for the corresponding plug, or socket, arrangement of the first circuit board,
wherein that of the two arrangements, which is not secured on the first circuit board, is correspondingly arranged on that electronics module, to which the circuit board seat is not secured.

13. The field device as claimed in claim 12, wherein the circuit board seat includes a second guide, which is designed orthogonally to guide the corresponding plug or socket arrangement relative to the surface of the first circuit board.

14. The field device as claimed in claim 12, wherein that electronics module, on which the circuit board seat is arranged, comprises a second circuit board, which is oriented orthogonally to the plug-in vector, and/or wherein the circuit board seat, and the corresponding arrangement, are arranged relative to the plug-in vector behind, or above, the second circuit board.

15. The field device as claimed in claim 14, wherein the circuit board seat is designed as a component of a potting form for the second circuit board.

16. The field device as claimed in claim 14, wherein the circuit board seat has on sides of that surface of the first circuit board, on which the corresponding arrangement is arranged, a yoke extending orthogonally to the plug-in vector, and wherein such surface of the first circuit board is electrically connected with the second circuit board via a flexible circuit board or a flexible cable.

17. The field device as claimed in claim 15, wherein the yoke surrounds in the circuit board seat an inner surface, which is smaller than a minimum extent of the corresponding arrangement on the first circuit board.

18. The field device as claimed in claim 12, wherein the circuit board seat includes an engagement hook opposite that surface of the first circuit board, on which the corresponding arrangement is arranged, such that the engagement hook forms in the first guide in the direction of the plug-in vector an end stop for the first circuit board after engagement.

19. The field device as claimed in claim 18, wherein the engagement hook is designed in such a manner that in the engaged state it exerts a compressive force on the first circuit board orthogonally to the surface of the first circuit board.

20. The field device as claimed in claim 12, wherein at least that of the two arrangements, which is secured to the first circuit board, is designed as an SMD component or as a THT component.

21. The field device as claimed in claim 12, wherein the mechanical securement of the electronic modules comprises at least three engagement tabs and corresponding projections.

22. A method for producing a field device,
wherein the field device includes: a housing having an inner space, a first electronics module secured in the inner space, a second electronics module arranged in the inner space, a mechanical securement, by means of which the second electronics module is securable to the first electronics module along a defined plug-in vector to form a mechanical connection, and an electrical plug contact, via which the second electronics module is electrically contactable with the first electronics module correspondingly to the mechanical connection in the direction of the plug-in vector, with a plug arrangement, a socket arrangement corresponding to the plug arrangement, a first circuit board having a surface, on which either the plug arrangement or the socket arrangement is arranged in such a manner that the plugs, or sockets, are oriented in parallel with the surface, and a circuit board seat, which is arranged at one of the two electronic modules, with a first guide, by means of which the first circuit board is guidable in parallel with the plug-in vector, and at least one end stop element, which forms in the first guide counter to the plug-in vector an end stop for the corresponding plug, or socket, arrangement of the first circuit board, wherein that of the two arrangements, which is not secured on the first circuit board, is correspondingly arranged on that electronics module, to which the circuit board seat is not secured;
wherein the method includes the steps of:
inserting the first circuit board into the guide grooves of the first guide of the circuit board seat,
mechanical and electrical connecting of the second electronics module to the first electronics module, in that
the socket arrangement is oriented relative to the plug-in vector aligned with the plug arrangement, and
the second electronics module is guided in the direction of the plug-in vector to accomplish the mechanical and electrical plugging in, and
securing the first electronics module in the inner space of the housing of the field device.
